(19) United States
(12) Patent Application Publication
(10) Pub. No.: US 2007/0191232 A1
(43) Pub. Date: Aug. 16, 2007

(54) Superconductor Wire Material Having Structure For Inhibiting Crack, Superconductor Power Cable Using The Same And Manufacturing Method Thereof

(76) Inventors: Bong-ki Ji, Gyeonggi-do (KR); Do-Woon Kim, Gyeonggi-do (KR); Byoung-kwang Lee, Gyeonggi-do (KR); Hyung-mok Kim, Gyeonggi-do (KR)

Correspondence Address: JONES DAY, 222 EAST 41ST ST, NEW YORK, NY, 10017, US

(21) Appl. No.: 11/579,762

(22) PCT Filed: Nov. 25, 2005
(86) PCT No.: PCT/KR05/04002

§ 371 Date: Nov. 7, 2006

(30) Foreign Application Priority Data
Nov. 25, 2004 (KR) 10-2004-0097386

(51) Int. Cl. H01L 39/24

(52) U.S. Cl. 505/434

(57) ABSTRACT

Disclosed is a superconductor wire material that configures a conductive layer in a banded state. The superconductor wire material includes a substrate made of metal; at least one buffer layer laminated on the substrate; and a superconductive layer laminated on the buffer layer, wherein, when the superconductor wire material is banded, a banding diameter (D) of the superconductor wire material and a thickness (t) of the substrate have the following relation: {t(D+t)}<0.004. Thus, when the superconductor wire material is banded, it is possible to inhibit a crack from being generated between the buffer layer and the superconductive layer of the superconductor wire material.

### TECHNICAL FIELD

The present invention relates to a superconductor wire material, a superconductor power cable, and its manufacturing method, and more particularly to a superconductor wire material having a structure capable of inhibiting a crack when it is used in a banded state, a superconductor power cable using the superconductor wire material, and its manufacturing method.

### BACKGROUND ART

A superconductor is a conductor whose electric resistance disappears at a very low temperature to lose energy very little, and it is applied as a superconductor wire material in various fields such as motors, power generators and wires of power cables. In such application fields, the superconductor wire material is generally used in a banded state, and as a representative example, it is banded in a superconductor power cable to form a superconductive layer.

FIG. 1 is a perspective view showing a general superconductive power cable. Referring to FIG. 1, the superconductive power cable includes a former 20 acting as a flow path of a coolant for cooling the cable below a critical temperature so that a superconductor wire material keeps its superconductivity, conductive layers 10 composed of a superconductor wire material banded around the former 20, insulating layers 30 interposed between the conductive layers 10 for insulation between the conductive layers 10, and a shield layer 40 for electric shielding of the cable and protection against external environments. The superconductor wire material composing the conductive layers 10 has a structure that a metal substrate, a ceramic buffer layer and a superconductive layer are subsequently laminated, and it is banded around the former 20 with a certain radius of curvature.

However, the superconductor wire material used in a banded state as mentioned above receives a tensile stress to the superconductive layer and the buffer layer composed of thin ceramic during the banding procedure, thereby causing micro cracks. Cracks caused in the buffer layer deteriorate a matching state of epitaxial crystalline structures between the superconductive layer and the buffer layer, and cracks caused in the superconductive layer act as a factor deteriorating electric connection of supercurrent. current.

### DISCLOSURE OF INVENTION

### Technical Problem

The present invention is designed in consideration of the above problems, and therefore it is an object of the invention to provide a superconductor wire material having a structure not causing cracks between a buffer layer and a superconductive layer of the superconductor wire material when the superconductor wire material is used in a banded state.

### Technical Solution

In order to accomplish the above object, the present invention provides a super-conductor wire material that configures a conductive layer in a banded state, which includes a substrate made of metal; at least one buffer layer laminated on the substrate; and a superconductive layer laminated on the buffer layer, wherein, when the super-conductor wire material is banded, a banding diameter (D) of the superconductor wire material and a thickness (t) of the substrate have the following relation:

$$\frac{t}{D + t} ≺ 0.004$$

Here, the thickness (t) of the substrate is preferably 30 to 200 mm.

In addition, the substrate may be a layer of any one material selected from the group consisting of Ni, Ni-alloy, Cu, Cu-alloy, Ag, Co, Mo, Cd, Pd and Pt.

Meanwhile, the buffer layer may be a layer of any one material selected from the group consisting of ZrO₂, CeO₂, YSZ, Y₂O₃ and HfO₂, or a combination of at least two layers thereof.

Preferably, the buffer layer may be composed of three layers of CeO₂, YSZ and CeO₂.

As an alternative, the buffer layer may be composed of three layers of Y₂O₃, YSZ and CeO₂.

In another aspect of the invention, there is also provided a superconductor power cable having at least one superconductor wire material banded around a former that is a flow path of a coolant, the superconductor wire material satisfying the following relation:

$$\frac{t}{D + t} ≺ 0.004$$

In still another aspect of the invention, there is also provided a method for manufacturing a superconductor power cable, which includes a step of banding at least one layer of a superconductor wire material around a former that is a flow path of a coolant, the superconductor wire material satisfying the following relation:

$$\frac{t}{D + t} ≺ 0.004$$

### BRIEF DESCRIPTION OF THE DRAWINGS

These and other features, aspects, and advantages of preferred embodiments of the present invention will be more fully described in the following detailed description, taken accompanying drawings. In the drawings:

FIG. 1 is a perspective view showing a general superconductor power cable;

FIG. 2 is a sectional view schematically showing a superconductor wire material according to the present invention; and

FIG. 3 is a sectional view showing a banded shape of the superconductor wire material according to the present invention.

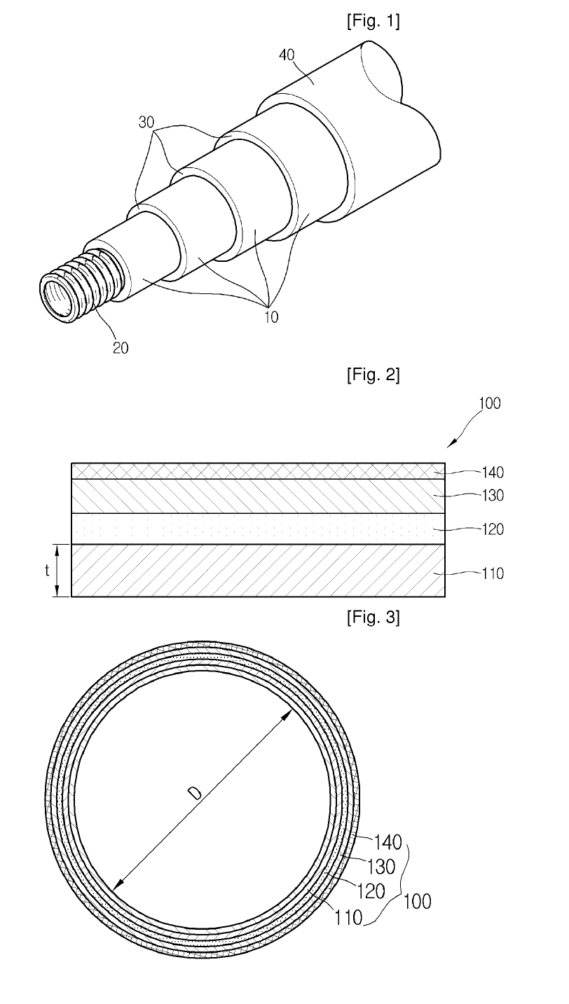

### BEST MODE FOR CARRYING OUT THE INVENTION

The present invention will be described in detail referring to the drawings, the terms used should not be construed as limited to general and dictionary meanings but based on the meanings and concepts of the invention on the basis of the principle that the inventor is allowed to define terms appropriate for the best explanation. Therefore, the descriptionherein the scope of the invention be understood that other and modifications could be made thereto without departing from the spirit and scope of the invention.

FIG. 2 is a sectional view schematically showing a superconductor wire material according to the present invention, and FIG. 3 is a sectional view showing a banded state of the superconductor wire material according to the present invention.

Referring to FIGS. 2 and 3, the superconductor wire material 100 of the present invention includes a substrate 110 made of metal, a buffer layer 120 laminated on the substrate 110, and a superconductive layer 130 laminated on the buffer layer 120.

The substrate 110 is made of metal material. Preferably, the substrate 110 may be a layer of any material selected from the group consisting of Ni, Ni-alloy, Cu, Cu-alloy, Ag, Co, Mo, Cd, Pd and Pt.

In addition, the substrate 110 is prepared to have a cube aggregate texture by rolling and heat treatment. For this purpose, the well-known RABiTs™ (Rolling Assisted Biaxially Textured Substrate) may be used.

The thickness t of the substrate 110 has a relation as in the following equation 1 with a banding diameter D when the superconductor wire material is banded as mentioned above.

$$\frac{t}{D + t} ≺ 0.004 \qquad MathFigure 1$$

If the thickness t of the substrate 110 and the banding diameter D have the relation as in the equation 1, it is possible to inhibit cracks from being generated in the buffer layer 120 and the superconductive layer 130 included in the superconductor wire material, as might be found in experimental examples explained later.

The thickness t of the substrate 110 is determined depending on an entire diameter of the superconductor power cable, and preferably ranged from 30 mm to 200 mm.

The buffer layer 120 buffers crystalline structure mismatching between the substrate 110 and the superconductive layer 130 and also prevents substances of the substrate 110 from being dispersed to the superconductive layer 130 and thus deteriorating superconductive characteristics.

The buffer layer 120 is for example epitaxially laminated on the substrate 110 using PLD (Pulsed Laser Ablasion), sputtering, or CVD (Chemical Vapor Deposition). However, the present invention is not limited to the above.

Preferably, the buffer layer 120 is composed of a layer of any one material selected from the group consisting of ZrO₂, CeO₂, YSZ, Y₂O₃ and HfO₂, or a combination of at least two layers thereof. More preferably, the buffer layer 120 is composed of three layers of CeO₂, YSZ and CeO₂. As an alternative, the buffer layer 120 is composed of three layers of Y₂O₃, YSZ and CeO₂.

The superconductive layer 130 transfers power in a superconductive state below a critical temperature.

The superconductive layer 130 is epitaxially laminated on the buffer layer 120 using electron beam evaporation, PLD, sputtering, CVD and so on. However, the present invention is not limited thereto.

The superconductive layer 130 may be made of a mixture of Y(THD), Ba(THD) and Cu(THD). However, various kinds of superconductive materials well known in the art may be used, not limited thereto.

The superconductor wire material 100 according to the present invention further includes a protective layer 140 laminated on the superconductive layer 130. The protective layer 140 acts for protecting the superconductor wire material when an overcurrent flows on the wire material, and the protective layer 140 is for example made of metal material with a low electric resistance such as silver and copper.

Hereinafter, specific experimental examples are illustrated for the help of better understanding of the present invention.

Generally, an elongation may be expressed as shown in the following equation 2.

$$ɛ = \frac{Δ l}{{l}_{0}} = \frac{l - {l}_{0}}{{l}_{0}} \qquad MathFigure 2$$

Here, lₒ is a length before extension, and l is a length after extension.

When the superconductor wire material 100 is banded, the substrate 110 made of metal is elongated, but the buffer layer 120 and the superconductive layer 130 are not elongated but cause a crack at any instant. At this time, when the superconductor wire material 100 is banded, an approximate upper end portion of the substrate 110 receives a tensile force, but an approximate lower end portion receives a compressing force. Thus, in a central portion of the substrate 110, there is a region that is neither tensioned nor compressed. A circumferential length of this region is defined as lₒ that is a length before extension. Meanwhile, a portion substantially receiving a tensile force is the approximate upper end portion of the substrate 110, so a circumferential length corresponding to the upper end portion of the substrate 110 is defined as l that is a length after extension. lₒ and l may be mathematically expressed as in the following equations 3 and 4.

$$\begin{matrix}{l}_{0} = 2 π ( \frac{D}{2} + \frac{t}{2} ) & MathFigure 3 \\ l = 2 π ( \frac{D}{2} + t ) & MathFigure 3\end{matrix}$$

By arranging the equations 3 and 4 using the equation 2, an equation for elongation is induced as in the following equation 5.

$$ɛ = \frac{t}{D + t} \qquad MathFigure 5$$

The equation 5 may be used as an equation for the elongation of a superconductor wire material.

Hereinafter, it will be described based on actual experiments whether a crack is generated and what is the elongation calculated by the equation 5 according to various values of the banding diameter D of the superconductor wire material and the thickness t of the substrate.

First, superconductor wire materials 100 were prepared with changing the thickness t of the substrate 110 of the superconductor wire material 100 in various ways. After that, the superconductor wire materials 100 were banded. At this time, with changing the banding diameter D in various values, it was checked whether a crack was generated in the buffer layer 120 or the superconductive layer 130 of the super-conductor wire material, and the results are shown in the following table 1. In the experiments, the buffer layer 120 had one to three layers, and the total thickness of the entire buffer layer 120 was 3 to 5 mm

TABLE 1

| | Thickness | | | |
|---|---|---|---|---|
| | of | Banding | | |
| | Substrate | Diameter | | |
| | D (μm) | D (mm) | t/(D + t) | Cracks |
| Example 1 | 30 | 40 | less than 0.001 | not generated |
| Example 2 | 30 | 70 | less than 0.001 | not generated |
| Example 3 | 30 | 100 | less than 0.001 | not generated |
| Example 4 | 60 | 40 | 0.001˜0.002 | not generated |
| Example 5 | 60 | 70 | less than 0.001 | not generated |
| Example 6 | 60 | 100 | less than 0.001 | not generated |
| Example 7 | 100 | 40 | 0.002˜0.003 | not generated |
| Example 8 | 100 | 70 | 0.001˜0.002 | not generated |
| Example 9 | 100 | 100 | less than 0.001 | not generated |
| Example 10 | 150 | 40 | 0.003˜0.004 | not generated |
| Example 11 | 150 | 70 | 0.002˜0.003 | not generated |
| Example 12 | 150 | 100 | 0.001˜0.002 | not generated |
| Example 13 | 200 | 40 | more than 0.004 | generated |
| Example 14 | 200 | 70 | 0.002˜0.003 | not generated |
| Example 15 | 200 | 100 | 0.001˜0.002 | not generated |

Seeing the table 1, it would be found that a crack is was generated when an elongation of the superconductor wire material was not greater than 0.004 when calculated by the equation 5 (all experimental examples except for the experimental example 13), while a crack was generated when the elongation was 0.004 or above (the experimental example 13). Hence, it would be understood that a crack is not generated only when the equation 1 is satisfied. Thus, if a superconductor wire material is made to meet the equation 1, it is possible to inhibit cracks in the buffer layer and the super-conductive layer.

The present invention has been described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

### INDUSTRIAL APPLICABILITY

The superconductor wire material according to the present invention does not cause a crack in a buffer layer and a superconductive layer when being banded. Thus, when the superconductor wire material is finally produced, its characteristics are not deteriorated but the superconductor wire material may transmit super-current more reliably.

1. A superconductor wire material that configures a conductive layer in a banded state, the superconductor wire material comprising:
a substrate made of metal;
at least one buffer layer laminated on the substrate; and
a superconductive layer laminated on the buffer layer,
wherein, when the superconductor wire material is banded, a banding diameter (D) of the superconductor wire material and a thickness (t) of the substrate have the following relation:
$$\frac{t}{D + t} ≺ 0.004$$

2. The superconductor wire material according to claim 1, wherein the thickness (t) of the substrate is 30 to 200 mm.

3. The superconductor wire material according to claim 1, wherein the substrate is a layer of any one material selected from the group consisting of Ni, Ni-alloy, Cu, Cu-alloy, Ag, Co, Mo, Cd, Pd and Pt.

4. The superconductor wire material according to claim 1, wherein the buffer layer is a layer of any one material selected from the group consisting of ZrO₂, CeO₂, YSZ, Y₂O₃ and HfO₂, or a combination of at least two layers thereof.

5. The superconductor wire material according to claim 1, wherein the buffer layer is composed of three layers of CeO₂, YSZ and CeO₂.

6. The superconductor wire material according to claim 1, wherein the buffer layer is composed of three layers of Y₂O₃, YSZ and CeO₂.

7. A superconductor power cable having at least one superconductor wire material banded around a former that is a flow path of a coolant, the superconductor wire material comprising:
a substrate made of metal;
at least one buffer layer laminated on the substrate; and
a superconductive layer laminated on the buffer layer,
wherein a banding diameter (D) of the superconductor wire material and a thickness (t) of the substrate have the following relation:
$$\frac{t}{D + t} ≺ 0.004$$

8. The superconductor power cable according to claim 7, wherein the thickness (t) of the substrate is 30 to 200 mm.

9. The superconductor power cable according to claim 7, wherein the substrate is a layer of any one material selected from the group consisting of Ni, Ni-alloy, Cu, Cu-alloy, Ag, Co, Mo, Cd, Pd and Pt.

10. The superconductor power cable according to claim 7, wherein the buffer layer is a layer of any one material selected from the group consisting of ZrO₂, CeO₂, YSZ, Y₂O₃ and HfO₂, or a combination of at least two layers thereof.

11. The superconductor power cable according to claim 7, wherein the buffer layer is composed of three layers of CeO₂, YSZ and CeO₂.

12. The superconductor power cable according to claim 7, wherein the buffer layer is composed of three layers of Y₂O₃, YSZ and CeO₂.

13. The superconductor power cable according to claim 7, wherein a plurality of layers of the superconductor wire material are banded around the former, and insulating layers are interposed between the plurality of layers of the super-conductor wire material.

14. A method for manufacturing a superconductor power cable, which includes a step of banding at least one layer of a superconductor wire material around a former that is a flow path of a coolant, the superconductor wire material comprising:
a substrate made of metal;
at least one buffer layer laminated on the substrate; and
a superconductive layer laminated on the buffer layer,
wherein, when the superconductor wire material is banded around the former, a banding diameter (D) of the superconductor wire material and a thickness (t) of the substrate have the following relation:
$$\frac{t}{D + t} ≺ 0.004$$

15. The method for manufacturing a superconductor power cable according to claim 14, wherein the thickness (t) of the substrate is 30 to 200 mm.

16. The method for manufacturing a superconductor power cable according to claim 14, wherein the substrate is a layer of any one material selected from the group consisting of Ni, Ni-alloy, Cu, Cu-alloy, Ag, Co, Mo, Cd, Pd and Pt.

17. The method for manufacturing a superconductor power cable according to claim 14, wherein the buffer layer is a layer of any one material selected from the group consisting of ZrO₂, CeO₂, YSZ, Y₂O₃ and HfO₂, or a combination of at least two layers thereof.

18. The method for manufacturing a superconductor power cable according to claim 14, wherein the buffer layer is composed of three layers of CeO₂, YSZ and CeO₂.

19. The method for manufacturing a superconductor power cable according to claim 15, wherein the buffer layer is composed of three layers of Y₂O₃, YSZ and CeO₂.

20. The method for manufacturing a superconductor power cable according to claim 14, wherein, when the superconductor wire material is banded around the former, a plurality of layers of the superconductor wire material are banded with insulating layers being interposed therebetween.
